(19) United States
(12) Patent Application Publication
(10) Pub. No.: US 2006/0114365 A1
(43) Pub. Date: Jun. 1, 2006

(54) Manufacturing method of electrooptical device and image forming apparatus

(75) Inventor: Katsuhiro Takahashi, Shiojiri (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/260,752

(22) Filed: Oct. 27, 2005

(30) Foreign Application Priority Data
Nov. 29, 2004 (JP) 2004-343424

(51) Int. Cl. G02F 1/1335

(52) U.S. Cl. 349/57

(57) ABSTRACT

A method for manufacturing an electrooptical device, in which a luminous element is formed on a luminous element formation surface of a transparent substrate and in which a microlens that outputs light emitted from the luminous element is formed on a light-extracting surface of the transparent substrate, including: forming the light-extracting surface by grinding one surface of the transparent substrate opposite from the luminous element formation surface towards the luminous element formation surface after applying a support substrate to the luminous element formation surface side of the transparent substrate.

### BACKGROUND

1. Technical Field

The present invention relates to an electrooptical device manufacturing method and an image forming apparatus.

2. Related Art

In an image forming apparatus using an electrophotographic method, an exposure head is used as an electrooptical device for forming a latent image by exposing a photosensitive drum as an image carrier. In recent years, in order to produce a thinner and lighter exposure head, the exposure head using an organic electroluminescence element (organic EL element) as its light emitting source has been proposed.

For this type of exposure head, in particular, a so-called bottom emission structure is employed because it allows a wide choice of the constituent materials, the bottom emission structure being that the organic EL element is formed on one surface (a luminous element formation surface) of a transparent substrate and that light emitted from the organic EL element is extracted from the other surface (light-extracting surface) opposite from the luminous element formation surface.

However, with the bottom emission structure, various kinds of wires, capacitances, and the like are formed between the light-extracting surface and the organic EL element in order to emit the organic EL element. Therefore, there is a problem in that an aperture ratio of the organic EL element decreases, thereby decreasing light extraction efficiency.

Therefore, in order to increase the light extraction efficiency with this type of exposure head, it is proposed to provide a lens, or a so-called microlens, that condenses the light emitted from the organic EL element on the light-extracting surface (e.g., JP-A-2003-291404). In JP-A-2003-291404, the microlens is formed by discharging a curing resin onto the light-extracting surface opposite from the organic EL element and by curing this discharged resin.

However, with the above-referenced exposure head, the microlens detaches from the organic EL element by a distance between the luminous element formation surface and the light-extracting surface, that is, by the thickness of the transparent substrate. Therefore, an aperture angle of the microlens to the organic EL element (an angle set between the center of the organic EL element and the diameter of the microlens) becomes smaller by the thickness of the transparent substrate, and it creates a problem of impairing efficiency in the extraction of the light emitted from the organic EL element.

It is considered possible to alleviate these problems by reducing the thickness of the transparent substrate and forming the organic EL element and the microlens on such a transparent substrate. However, if the transparent substrate becomes thinner, the transparent substrate will lose some of its mechanic strength and possibly be damaged when forming the organic EL element and the microlens.

### SUMMARY

An advantage of the invention is to provide an electrooptical device manufacturing method and an image forming apparatus having improved efficiency in the extraction of light emitted from the luminous element.

According to an aspect of the invention, a method for manufacturing an electrooptical device, in which a luminous element is formed on a luminous element formation surface of a transparent substrate and in which a microlens that outputs light emitted from the luminous element is formed on a light-extracting surface of the transparent substrate, includes: forming the light-extracting surface by grinding one surface of the transparent substrate opposite from the luminous element formation surface towards the luminous element formation surface after applying a support substrate to the luminous element formation surface side of the transparent substrate.

According to the method for manufacturing the electrooptical device of the invention, by applying the support substrate to support the transparent substrate, it is possible to grind one surface of the transparent substrate opposite from the luminous element formation surface towards the luminous element formation surface. Further, it is possible to bring the light-extracting surface close to the luminous element formation surface by the amount ground from the one surface, and, thereby, the distance between the luminous element and the microlens can be reduced. As a result, it is possible to widen the aperture angle of the microlens to the luminous element and to manufacture the electrooptical device with the improved efficiency in the extraction of light emitted from the luminous element.

The method for manufacturing the electrooptical device may further include forming the light-extracting surface by grinding the one surface of the transparent substrate.

In this case, the distance between the luminous element formation surface and the light-extracting surface can be shortened only by the amount ground from one surface of the transparent substrate, and it is possible to manufacture the electrooptical device with improved efficiency in the extraction of light emitted from the luminous element.

The method for manufacturing the electrooptical may further include forming the light-extracting surface by etching the one surface of the transparent substrate.

In this case, the distance between the luminous element formation surface and the light-extracting surface can be reduced by the amount etched from the one surface of the transparent substrate, and it is possible to manufacture the electrooptical device with improved efficiency in the extraction of light emitted from the luminous element.

The method for manufacturing the electrooptical device may further include forming the microlens by forming a droplet on the light-extracting surface using a functional liquid discharged from a droplet discharging apparatus and by curing the droplet.

In this case, because the microlens is formed using the functional liquid discharged from the droplet discharging apparatus, it is possible to form the microlens without having restrictions on the thickness of the transparent substrate and to manufacture the electrooptical device with the improved light extraction efficiency.

The method for manufacturing the electrooptical device may further include forming the microlens in a convex shape by forming the droplet in a half spherical shape on the light-extracting surface at a position opposite from the luminous element and by curing the droplet.

In this case, since the microlens is formed using the convex lens, it is possible to improve the efficiency in condensing the light emitted from the luminous element by use of the microlens. As a result, it is easier to manufacture the electrooptical device with improved efficiency in extracting and condensing the light.

In the method for manufacturing the electrooptical device, the luminous element may be an electroluminescence element containing a transparent electrode formed on the light-extracting surface side, a rear surface electrode formed opposite from the transparent electrode, and a luminescent layer formed between the transparent electrode and the rear surface electrode.

In this case, it is possible to manufacture the electrooptical device with improved efficiency in extraction of light emitted from the electroluminescence element.

In the method for manufacturing the electrooptical device, the luminescent layer may be formed using an organic material, and the electroluminescence element may be an organic electroluminescence element.

According to this method for manufacturing the electrooptical device, it is possible to manufacture the electrooptical device with the improved efficiency in the extraction of light emitted from the organic electroluminescence element.

According to another aspect of the invention, an image forming apparatus of the invention having a charging unit that charges the peripheral surface of an image carrier, an exposure unit that exposes the charged peripheral surface of the image carrier so as to form a latent image, a developing unit that develops an image by supplying coloring particles to the latent image, and a transfer unit that transfers the developed image to a transfer medium, in that the exposure unit is provided with the electrooptical device manufactured by the electrooptical device manufacturing method.

According to the image forming apparatus of the invention, the exposure unit that exposes the charged image carrier is provided with the above-described electrooptical device. Thus, it is possible to improve the light extraction efficiency of the image forming apparatus in the exposure.

### BRIEF DESCRIPTION OF THE DRAWINGS

The invention will be described with reference to the accompanying drawings, wherein like numbers reference like elements.

FIG. 1 is a schematic sectional side view of an image forming apparatus embodying the invention.

FIG. 2 is a schematic sectional front view of an exposure head.

FIG. 3 is a schematic sectional planar view of the exposure head.

FIG. 4 is an enlarged sectional view of the exposure head.

FIG. 5 is a flowchart to explain a method for manufacturing the exposure head.

FIG. 6 is a diagram to explain a procedure for manufacturing the exposure head.

FIG. 7 is a diagram to explain the procedure for manufacturing the exposure head.

FIG. 8 is a diagram to explain the procedure for manufacturing the exposure head.

### DESCRIPTION OF EXEMPLARY EMBODIMENT

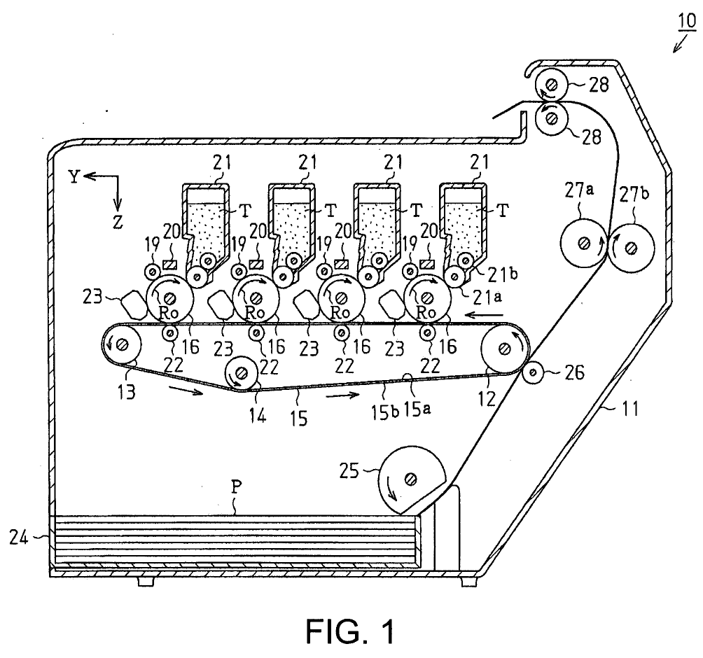

One working example embodying the invention will now be described with reference to FIGS. 1 to 8. FIG. 1 is a schematic sectional side view of an electrophotographic printer as the image forming apparatus.

Electrophotographic Printer

As shown in FIG. 1, an electrophotographic printer 10 (hereinafter referred to simply as a printer 10) includes a case 11 formed in a box-like shape. The case 11 includes therein a driving roller 12, a driven roller 13, a tension roller 14, and an intermediate transfer belt 15 as a transfer medium pulled and set against each of the rollers 12-14. Further, by rotating the driving roller 12, the intermediate transfer belt 15 can be cyclically driven in an arrow direction as shown in FIG. 1.

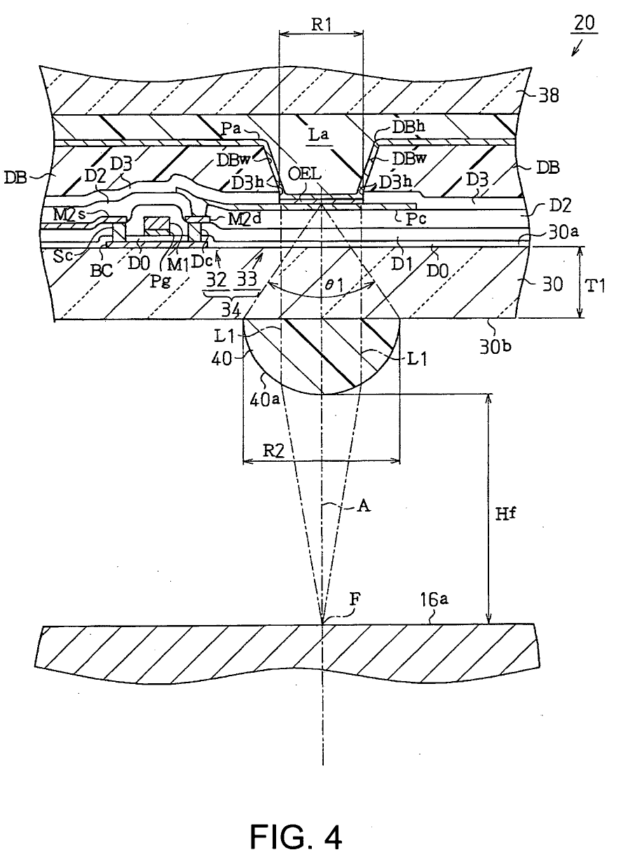

On the upper part of the intermediate transfer belt 15, four photosensitive drums 16 as image carriers are provided in a manner that they are rotatable in a pulling direction (a sub scanning direction Y) of the intermediate transfer belt 15. On peripheral surfaces of the photosensitive drums 16, there are formed light conductive photosensitive layers 16a (see FIG. 4). Once the photosensitive layers 16a are positively or negatively charged in a dark place and irradiated by light having a predetermined wavelength range, the charges at the irradiated parts are erased. In other words, the electrophotographic printer 10 is a tandem type printer composed of these four photosensitive drums 16.

Around each photosensitive drum 16, there are provided a charging roller 19 as a charging unit, an organic electroluminescence array exposure head 20 (hereinafter referred to simply as the exposure head 20) as the electrooptical device constituting the exposure unit, a toner cartridge 21 as a developing unit, a primary transfer roller 22 constituting a transfer unit, and a cleaning unit 23.

The charging roller 19 is a semiconductive rubber roller closely contacting the photosensitive drum 16. When a direct voltage is applied to this charging roller 19 to rotate the photosensitive drum 16, the photosensitive layer 16a of the photosensitive drum 16 becomes charged to have a predetermined charged potential on its entire peripheral surface.

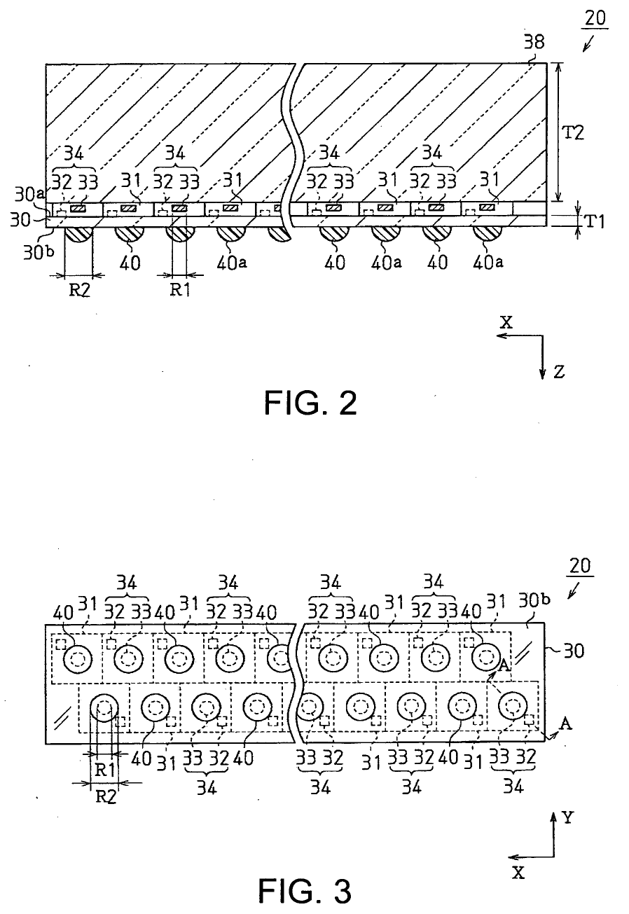

The exposure head 20 is a light source that beams light having a predetermined wavelength region and is formed in a shape of a long plate as shown in FIG. 2. This exposure head 20 is positioned apart from the photosensitive layer 16a only by a predetermined distance, with its longitudinal direction being in parallel with an axial direction (a direction perpendicular to a paper surface in FIG. 1: a main scanning direction X) of the photosensitive drum 16. Then, when the exposure head 20 beams light based on print data in a vertical direction Z (see FIG. 1), and then the photosensitive drum 16 rotates in a rotational direction Ro, the photosensitive layer 16a is exposed to the light having the predetermined wavelength region. Consequence, the photosensitive layer 16a loses the charges at the irradiated part (an exposure spot), thereby forming an electrostatic image (an electrostatic latent image) on its peripheral surface. In addition, the wavelength region of the light exposed by the exposure head 20 is a wavelength region matching with the polarizing sensitivity of the photosensitive layer 16a. That is, the peak wavelength of the luminous energy of the light exposed by the exposure head 20 is set to almost match with the peak wavelength of the polarizing sensitivity of the photosensitive layer 16a.

The toner cartridge 21 is formed in a shape of a box and holds therein a toner T as a coloring particle having a diameter of around 10 μm. Further, four toner cartridges 21 in the embodiment hold four respective colors (black, cyan, magenta, and yellow). The toner cartridges 21 are each provided with a developing roller 21a and a supply roller 21b when seen from the side of the photosensitive drum 16. The supply roller 21b rotates so as to transport the toner T to the developing roller 21a. By friction or the like with the supply roller 21b, the developing roller 21a charges the toner T transported by the supply roller 21b and, at the same time, attaches the charged toner T evenly to the peripheral surface of the developing roller 21a.

Then, the supply roller 21b and the developing roller 21b rotate in a state that a bias potential almost equivalent to the aforementioned charged potential is being applied to the photosensitive drum 16. The photosensitive drum 16 then applies electrostatic attraction corresponding to the bias potential between the aforementioned exposure spot and the developing roller 21a (the toner T). The toner T applied with the electrostatic attraction moves from the peripheral surface of the developing roller 21a to the exposure spot so as to get absorbed. As a consequence, a visible monochrome image (a developed image) corresponding to each electrostatic latent image is formed (developed) on the peripheral surface of each photosensitive drum 16 (each photosensitive layer 16a).

The primary transfer roller 22 is provided at a position opposite from each photosensitive drum 16 on the inner surface 15a of the intermediate transfer belt 15. The primary transfer roller 22 is a conductive roller and rotates with its peripheral surface closely contacting the inner surface 15a of the intermediate transfer belt 15. When the direct voltage is applied to the primary transfer roller 22 to rotate the photosensitive drum 16 and the intermediate transfer belt 15, the toner T absorbed in the photosensitive layer 16a moves successively on an outer surface 15b of the intermediate transfer belt 15 and is absorbed because of the electrostatic attraction towards the primary transfer roller 22. That is, the primary transfer roller 22 primarily transfers the developed image formed on the photosensitive drum 16 onto the outer surface 15b of the intermediate transfer belt 15. Then, the outer surface 15b of the intermediate transfer belt 15 repeats the primary transfer of the developed monochrome image for four times using the photosensitive drum 16 and the primary transfer roller 22, and the developed images are overlapped to produce a full-color image (a toner image).

The cleaning unit 23 includes a light source such as an LED and a rubber blade (not shown) and eliminates charges from the photosensitive layer 16a that was beamed with light and charged after the primary transfer. Then, with the rubber blade, the cleaning unit 23 mechanically removes the toner T remained on the discharged photosensitive layer 16a.

Under the intermediate transfer belt 15, there is provided a recording paper cassette 24 holding a recording paper P. Above the recording paper cassette 24, there is a feeding roller 25 that feeds the recording paper P to the intermediate transfer belt 15. A secondary transfer roller 26 constituting the transfer unit is positioned opposite the driving roller 12 above the feeding roller 25. The secondary transfer roller 26, which is the same conductive roller as the above-referenced primary transfer roller 22, presses the rear surface of the recording paper P and brings the main surface of the same recording paper P into contact with the outer surface 15b of the intermediate transfer belt 15. Then, when the direct voltage is applied to this secondary transfer roller 26 to rotate the intermediate transfer belt 15, the toner T absorbed in the outer surface 15b of the intermediate transfer belt 15 moves successively on the surface of the recording paper P so as to get absorbed. That is, the secondary transfer roller 26 secondarily transfers the toner image formed on the outer surface 15b of the intermediate transfer belt 15 onto the main surface of the recording paper P.

Above the secondary transfer roller 26, there is a heat roller 27a housing a heat source and a pressing roller 27b that presses this heat roller 27a. Further, when the secondarily-transferred recording paper P is transported between the heat roller 27a and the pressing roller 27b, the toner T that was transferred onto the recording paper P softens with heat and cures as it permeates into the recording paper P. As a consequence, the toner image is fixed on the surface of the recording paper P. The recording paper P having the fixed toner image is dispensed outside the case 11 by a dispensing roller 28.

Thus, the printer 10 exposes the charged photosensitive layer 16a using the exposure head 20 and forms the electrostatic latent image on the photosensitive layer 16a. Then, the printer 10 develops the electrostatic latent image of the photosensitive layer 16a so as to form the monochrome image of the photosensitive layer 16a on this photosensitive layer 16a. Thereafter, the printer 10 primarily transfers the developed image of the photosensitive layer 16a successively onto the intermediate transfer belt 15 so as to form the full-color toner image on the same intermediate transfer belt 15. Then, the printer 10 secondarily transfers the toner image on the intermediate transfer belt 15 onto the recording paper P and fixes the toner image by heat and pressure, thereby finishing the printing.

In the following, the exposure head 20 as the electrooptical device provided in the printer 10 will be described. FIG. 2 is a cross-sectional front view of the exposure head 20.

As shown in FIG. 2, the exposure head 20 is provided with an element substrate 30 as the transparent substrate. The element substrate 30 is a long, colorless, transparent non-alkali glass substrate formed to have a width in the longitudinal direction (a horizontal direction in FIG. 2: the main scanning direction X), which is about the same width as the width of the photosensitive drum 16 in the axial direction.

The element substrate 30 is formed so that its thickness is of an even thickness (a post-grind thickness T1) obtainable by a hereinafter-described grinding process. In the embodiment, the post-grind thickness T1 is 50 μm, but it is not limited thereto.

Further, in the embodiment, the upper surface of the element substrate 30 (the surface opposite from the photosensitive drum 16) is a luminous element formation surface 30a, and the lower surface of the element substrate 30 (the surface on the side of the photosensitive drum 16) is a light-extracting surface 30b.

First, the luminous element formation surface 30a of the element substrate 30 will be described. FIG. 3 is a plan view of the exposure head 20 seen from the side of the light-extracting surface 30b. FIG. 4 is a schematic cross sectional diagram taken along a dash-dotted line A-A shown in FIG. 3.

As shown in FIG. 2, there is a plurality of pixel formation regions 31 formed on the luminous element formation surface 30a of the element substrate 30. As shown in FIG. 3, the pixel formation regions 31 are arranged in a two-dimensional zigzag lattice shape, each having a thin film transistor 32 (hereinafter referred to simply as a TFT 32) and a pixel 34 composed of an organic electroluminescence element (an organic EL element) 33 as the luminous element. The TFT 32 turns to an on state by a data signal produced based on the print data and, based on this on status, makes the organic EL element 33 to emit light.

As shown in FIG. 4, the TFT 32 includes a channel film BC at the lowest layer. The channel film BC is an island-shaped p-type polysilicon film formed on the luminous element formation surface 30a, and, on both right and left sides thereof, there are formed an activated n-type region (a source region and a drain region) which is not shown in the drawings. In short, the TFT 32 is a so-called polysilicon type TFT.

At the upper middle position of the channel film BC and from the side of the luminous element formation surface 30a, there are formed a gate insulating film DO, a gate electrode Pg, and a gate wiring M1. The gate insulating film DO is an insulating film such as a silicon oxide film having optical transparency and is deposited on the channel film BC and on an almost entire surface of the luminous element formation surface 30a. The gate electrode Pg is a film made of low resistance metal such as tantalum and is formed opposite from the approximate center of the channel film BC. The gate wiring M1 is a transparent conductive film having the optical transparency such as an ITO and electrically couples the gate electrode Pg with a data line drive circuit (not shown). Then, when the data line drive circuit inputs the date signal to the gate electrode Pg via the gate wiring M1, the TFT 32 turns to an on state based on the data signal.

On the source region and drain region of the channel film BC, there are formed a source contact Sc and a drain contact Dc extending upward. Each of the contacts Sc and Dc is made of metal film that lowers contact resistance against the channel film BC. Further, these contacts Sc and Dc and the gate electrode Pg (the gate wiring M1) are electrically disconnected with each other by a first interlayer insulating film D1 composed of silicon oxide film or the like.

On each of the contacts Sc and Dc, there are formed a power line M2s and an anode line M2d, each composed of the low resistance metal film such as aluminum. The power line M2s electrically couples the source contact Sc with the drive power source (not shown). The anode line M2d electrically couples the drain contact Dc and the organic EL element 33. These power line M2s and anode line M2d are electrically disconnected by a second interlayer insulating film D2 composed of silicon oxide film or the like. Then, when the TFT 32 turns to an on state based on the data signal, a drive current corresponding to the data signal is supplied from the power line M2s (the drive power source) to the anode line M2d (the organic EL element 33).

As shown in FIG. 4, the organic EL element 33 is formed on the second interlayer insulating film D2. There is an anode Pc as the transparent electrode at the lowest layer of this organic EL element 33. The anode Pc is a transparent conductive film having optical transparency such as an ITO, with its one end being coupled to the anode line M2d.

On this anode Pc, a third interlayer insulating film D3 such as a silicon oxide film that electrically insulates each anode Pc is deposited. In this third interlayer insulating film D3, there is formed a circular hole (a position-matching hole D3h) opening upwards at the approximate center of the anode Pc. Further, in the embodiment, the diameter of the position-matching hole D3h is a matching diameter R1 and is, but not limited to, 50 μm.

On the third interlayer insulating film D3, a partition layer DB made of photosensitive polyimide resin or the like is deposited. In the partition layer DB, there is formed a conical hole DBh opening upward in a tapered shape at a position opposite from the position matching hole D3h. Further, a partition DBw is formed with the inner peripheral surface of this conical hole DBh.

On the anode Pc and inside the position-matching hole D3h, an organic electroluminescence layer (an organic EL layer) OEL made of a polymeric organic material is formed. In other words, the organic EL layer OEL is formed with the same outer diameter as the diameter (the matching diameter R1) of the position-matching hole D3h.

The organic EL layer OEL is an organic compound layer composed of two layers including an electron hole transmit layer and the luminescent layer On the organic EL layer OEL, there is formed a cathode Pa as the rear surface electrode made of metal film such as aluminum having light reflectivity. The cathode Pa is formed to cover the almost entire surface of the luminous element formation surface 30a so as to commonly supply a potential to each of the organic EL elements 33, with the pixels 34 sharing the same potential with each other.

In other words, the organic EL element 33 is the organic electroluminescence element (the organic EL element) composed of these anode Pc, organic EL layer, and cathode Pa, and the diameter of the organic EL layer OEL that outputs light emitted from the organic EL element is the inner diameter of the position-matching hole D3h, that is, the matching diameter R1 (50 μm).

There is a support substrate 38 adhered on the cathode Pa (the element substrate 30) by an adhesive layer La1. The support substrate 38 is a colorless, transparent, non-alkali glass substrate formed in the same size as that of the element substrate 30 when seen in a plan view direction, having a thickness (a support thickness T2) thick enough to give mechanical strength to the exposure head 20. In addition, in the embodiment, the support thickness T2 of this support substrate 38 is 500 μm but is not limited thereto.

Then, when the drive current corresponding to the data signal is supplied to the anode line M2d, the organic EL layer OEL emits light having the brightness corresponding to this drive current. In this case, the light emitted towards the cathode Pa (upwards in FIG. 4) is reflected by the same cathode Pa. Thus, most of the light emitted from the organic EL layer OEL is irradiated on the light-extracting surface 30b (on the photosensitive drum 16) through the anode Pc, the second interlayer insulating film D2, the first interlayer insulating film D1, the gate insulating film DO, and the element substrate 30.

Next, the light-extracting surface 30b side of the element substrate 30 will be described.

As shown in FIG. 2, each microlens 40 is formed on the light-extracting surface 30b of the element substrate 30 at a position opposite from each organic EL element 33. The microlens 40 is a convex-shaped lens having a half spherical optical surface with sufficient transparency against the wavelength of light emitted from the organic EL layer OEL, and is formed in a manner that the center of the organic EL element 33 (the organic EL layer OEL) is positioned on its optic axis A as shown in FIG. 4.

Further, in the embodiment, the diameter of the microlens 40 (an aperture diameter R2), that is 100 μm, is twice the diameter of the organic EL layer OEL (the matching diameter R1). As a consequence, the microlens 40 can beam the light emitted by the organic EL layer OEL to the light-extracting surface 30b without deteriorating the image quality in an area surrounding the microlens 40.

Further, the microlens 40 is positioned in a manner that the intersecting point (an image-side focal point F) of the optic axis A intersecting with rays (a parallel flux of rays L1) emitted from the organic EL element 33 along the optic axis A is positioned on the photosensitive layer 16a, and that the distance between the vertex of the curved lower surface (an emitting surface 40a) and the photosensitive layer 16a is an image-side focal distance Hf. As a consequence, the light emitted from the microlens 40 can form the exposure spot of a desired size on the photosensitive layer 16a.

Additionally, in the embodiment, an angle set between the center of the organic EL layer OEL and the diameter of the microlens 40 is an aperture angle θ1 of the microlens 40.

Method for Manufacturing Exposure Head

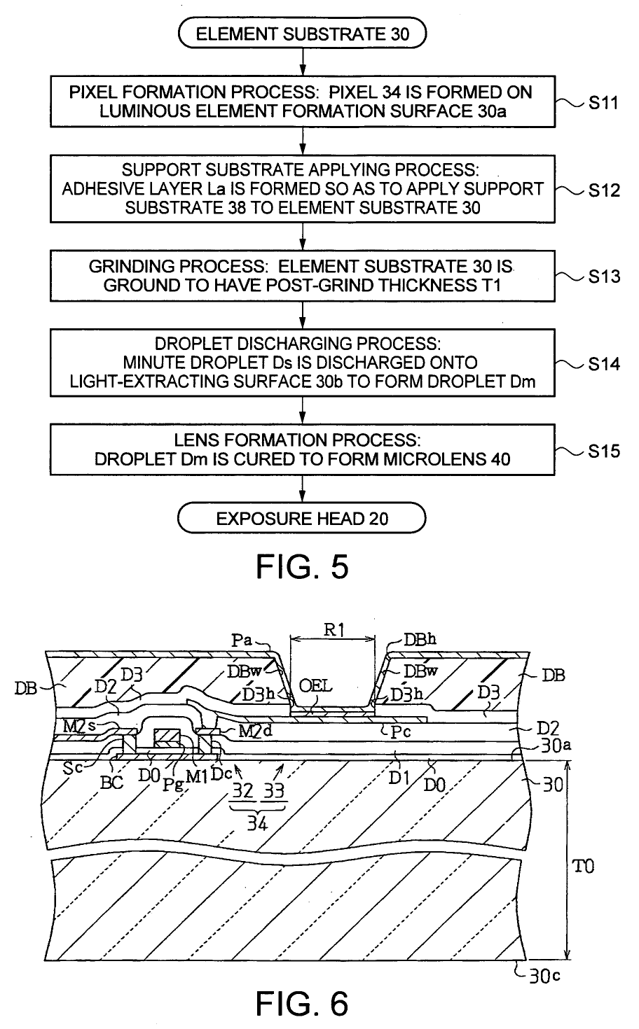

Now, the method for manufacturing the exposure head 20 will be described. FIG. 5 is a flowchart to explain the method for manufacturing the exposure head 20, and FIGS. 6-8 are diagrams to explain the method for forming the exposure head 20.

As shown in FIG. 5, a pixel formation process is first carried out (step S11), in which the pixel 34 is formed on the luminous element formation surface 30a of the element substrate 30.

In this case, the thickness of the element substrate 30 is a thickness having sufficient mechanical strength against the heat treatment, plasma treatment, and the like in the hereinafter-described pixel formation process and is formed to have a pre-grind thickness TO that is thicker than the post-grind thickness T1. Further, in the embodiment, the pre-grind thickness TO is 500 μm but is not limited thereto.

As shown in FIG. 6, in the pixel formation process, a polysilicon film crystallized by excimer laser or the like is first formed on the entire surface of the luminous element formation surface 30a. The polysilicon film is then patterned to form the channel film BC within each pixel formation region 31. After forming the channel film BC, the gate insulating film DO made of silicon oxide film or the like is formed on the entire upper surface of this channel film BC and the luminous element formation surface 30a, and the low resistance metal film such as tantalum is deposited on the entire upper surface of this gate insulating film DO. Then, the low resistance metal film is subjected to patterning so as to form the gate electrode Pg on the gate insulating film DO. When the gate insulating electrode Pg is formed, the n-type region (the source region and drain region) is formed in the channel film BC by an ion doping method using this gate electrode Pg as a mask.

Upon forming the source region and the drain region in the channel film BC, the transparent conductive film having the optical transparency such as the ITO is deposited on the entire surface of the gate electrode Pg and the gate insulating film DO, and this transparent conductive film is patterned to form the gate wiring M1 on the gate electrode Pg. When the gate wiring M1 is formed, the first interlayer insulating film D1 made of silicon oxide film or the like is formed on the entire surface of the gate wiring M1 and the gate insulating film DO by a plasma CVD method or the like. A pair of the contact holes is then patterned at a position corresponding to the source region and the drain region of this first interlayer insulating film D1. Then, by burying the metallic film into the contact hole, the source contact Sc and the drain contact Dc are formed.

After forming each of the contacts Sc and Dc, the metallic film such as aluminum is deposited on the entire surface of each of the contacts Sc and Dc and the first interlayer insulating film D1. This metallic film is then patterned to form the power line M2s and the anode line M2d that are to be coupled to each of the contacts Sc and Dc. Next, the second interlayer insulating film D2 made of silicon oxide film or the like is deposited on the entire surface of these power line M2s, anode line M2d, and the first interlayer insulating film D1. A via hole is then formed at a position opposing a part of the anode line M2d in the second interlayer insulating film D2. Thereafter, the transparent conductive film having the optical transparency such as the ITO is deposited inside the via hole and on the entire surface of the second interlayer insulating film D2. By patterning this transparent conductive film, the anode Pc to be coupled to the anode line M2d is formed.

When the anode Pc is formed, the third interlayer insulating film D3 made of silicon oxide film or the like is deposited on the entire surface of this anode Pc and the second interlayer insulating film D2. By patterning this third interlayer insulating film D3, the position matching hole D3h having the matching diameter R1 is formed. After forming the position matching hole D3h, the light curing resin is applied inside this posit ion matching hole D3h and on the entire surface of the third interlayer insulating film D3. This light curing resin is then patterned to form the partition layer DB having the partition DBw (the conical hole DBh).

Thereafter, a constituent material of the electron transmit layer is discharged into the position matching hole D3h (the conical hole DBh) by an ink-jet method or the like, and, by drying or curing the constituent material, the electron transmit layer is formed. Further, the constituent material of the luminescent layer is discharged onto this electron transmit layer by the inkjet method, followed by drying and curing of this constituent material to form the luminescent layer, that is, to form the organic EL layer OEL whose diameter is the matching diameter R1. Once the organic EL layer OEL is formed, the cathode Pa made of metal film such as aluminum is deposited on the entire surface of this organic EL layer OEL and the third interlayer insulating film D3 so as to form the organic EL element 33 composed of the anode Pc, the organic EL layer OEL, and the cathode Pa. As a consequence, the pixel 34 having the TFT 32 and the organic EL element 33 is formed.

During this process, the element substrate 30 is mechanically strained by various treatments such as heat treatment and plasma treatment. However, because the element substrate 30 is formed having the pre-grind thickness TO, such mechanical damage can be avoided.

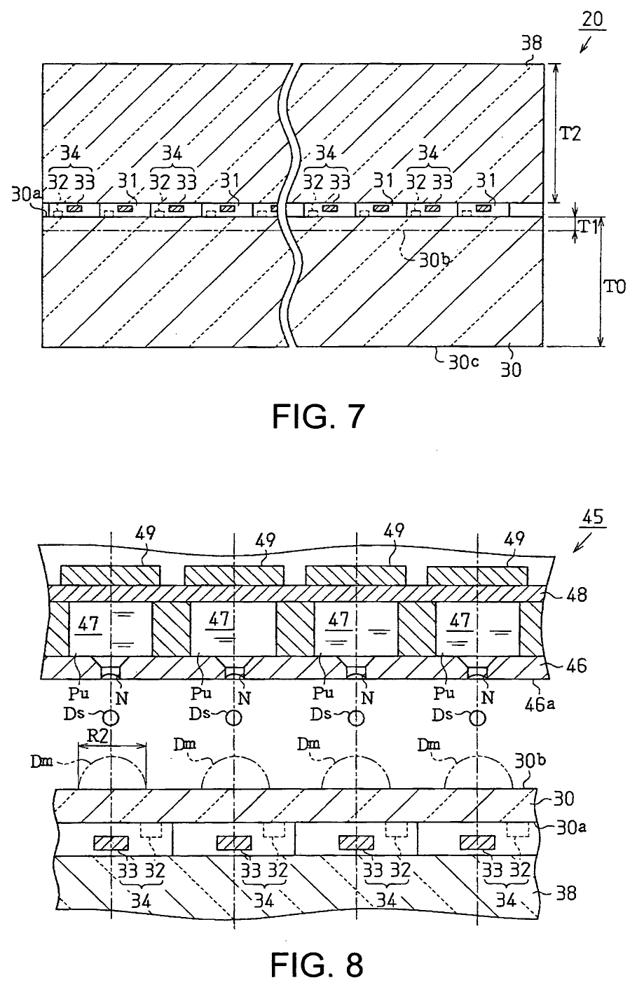

As shown in FIG. 5, after forming the pixel 34 on the luminous element formation surface 30a, a support substrate applying process is carried out (step S12), in which the support substrate 38 is applied to the element substrate 30. More specifically, an adhesive made of epoxy resin or the like is applied onto the entire surface of the pixel 34 (the cathode Pa) to form the adhesive layer La. Via this adhesive layer La, the support substrate 38 having the support thickness T2 (500 μm) is applied to the element substrate 30 as shown in FIG. 7.

As shown in FIG. 5, after applying the support substrate 38 to the element substrate 30, a grinding process is carried out (step S13), in which the element substrate 30 is subjected to grinding. More specifically, the support substrate 38 is supported by a supporting board and the like of a grinding apparatus (not shown), and, as shown in FIG. 7, a surface opposite from the luminescent element formation surface 30a (a grinding surface 30c), which is one of the surfaces of the element substrate 30, is ground with a grindstone or the like.

Then, the element substrate 30 is ground until the pre-grind thickness T0 is reduced to the post-grind thickness T1, and the light-extracting surface 30b (shown in a dash-dot-dotted line in FIG. 7) is thereby formed on the surface opposite from the luminous element formation surface 30a.

During this process, the element substrate 30 is mechanically strained by the grindstone and the like. However, the mechanical strength is complemented by the support substrate 38 having the support thickness T2, making it possible to avoid the mechanical damage.

As shown in FIG. 5, after the element substrate 30 is ground to have the post-grind thickness T1, a droplet discharging process is conducted (step S14), in which a droplet is discharged on the light-extracting surface 30b. FIG. 8 is a diagram to explain the droplet discharging process. First, the composition of the droplet discharging apparatus that discharges droplets will be described.

As shown in FIG. 8, a droplet discharge head 45 composing the droplet discharging apparatus is provided with a nozzle plate 46. A plurality of nozzles N, which discharge ultraviolet curing resin Pu as the functional liquid, are formed facing upward on the lower surface of the nozzle plate 46 (a nozzle formation surface 46a). Above each nozzle N, there is a supply chamber 47 which links to a tank (not shown) and enables the supply of the ultraviolet curing resin Pu into the nozzle N. On the supply chamber 47, there is a vibration plate 48 that increases and decreases the volume of the ultraviolet cured resin Pu inside the supply chamber 47 by vertically vibrating repeatedly. On the vibration plate 48 and at a position opposite the supply chamber 47, there is a piezoelectric element 49 that vibrates the vibration plate 48 by stretching and contracting vertically.

Then, as shown in FIG. 8, the element substrate 30 (the support substrate 38) to be transported to the liquid discharge apparatus is positioned in a manner that the light-extracting surface 30b formed in the grinding process comes in parallel with the nozzle forming surface 46a and that the center of each organic EL element 33 comes directly below the center of each nozzle N.

Now, when the drive signal is input to the droplet discharge head 45 in order to discharge the droplets, the piezoelectric element 49 stretches and contracts based on the same drive signal, thereby increasing and decreasing the volume in the supply chamber 47. When the volume of the supply chamber 47 decreases, the ultraviolet curing resin Pu in an amount equivalent to the decreased volume is discharged from each nozzle Z as a minute droplet Ds. The discharged minute droplet Ds lands on the light-extracting surface 30b at a position opposite the center of the organic EL element 33. Then, when the volume of the supply chamber 47 increases, the ultraviolet curing resin Pu in an amount equivalent to the increased volume is supplied from the tank (not shown) to the supply chamber 47. In other words, the liquid discharge head 45 discharges a predetermined volume of the ultraviolet curing resin Pu towards the light-extracting surface 30b by such increase and decrease of the volume in the supply chamber 47. The plurality of minute droplets Ds discharged on the light-extracting surface 30b are formed into the droplets Dm, as shown in dash-dot-dotted lines in FIG. 8, having a half spherical shape because of its surface tension and the like.

In this process, the droplet discharge head 45 discharges the minute droplet Ds whose diameter is almost the same as the aperture diameter R2 of the microlens 40, that is to say, only up to an amount equivalent to 100 μm.

As shown in FIG. 5, once the droplet Dm is formed on the light-extracting surface 30b, a lens formation process is carried out (step S15), in which the droplet Dm is cured to form the lens. More specifically, the droplet Dm (the light-extracting surface 30b) is irradiated by the ultraviolet rays and cured. As a consequence, the microlens 40 having the aperture diameter R2 (100 μm) is formed on the element substrate 30 having the post-grind thickness T1 (50 em), thereby producing the exposure head 20.

Further, the aperture angle θ1 of the microlens 40 can be widened only by the amount ground from the element substrate 30 (by the difference obtained by subtracting the post-grind thickness T1 from the pre-grind thickness T0, namely, 450 μm). Therefore, only by the amount ground from the element substrate 30, the quantity of light output from the emitting surface 40a of the microlens 40 can increase, and the efficiency in the extraction of light emitted from the organic EL element 33 can improve.

Next, the effect of the embodiment having the above-described structure will be hereinafter described.

1. According to the embodiment, the grinding surface 30c of the element substrate 30 having the organic EL element 33 formed thereon is ground to form the light-extracting surface 30b, and the microlens 40 is formed on this light-extracting surface 30b opposite from each organic EL element 33. Accordingly, it is possible to widen the aperture angle θ1 of the microlens 40 only by the amount ground from the element substrate 30, and, thus, the exposure head 20 with improved efficiency in the extraction of light emitted from the organic EL element 33 can be manufactured.

2. Moreover, by applying the support substrate 38 to the element substrate 30, the mechanical strength of the element substrate 30 is complemented. Accordingly, the grinding process (step S13), the droplet discharging process (step S14), and the lens formation process (step S15) can be carried out without damaging the organic EL element 33 and the element substrate 30, and it is thereby possible to more easily manufacture the exposure head 20 with the improved light extraction efficiency.

3. In the embodiment, the ultraviolet curing resin Pu is discharged from the droplet discharge head 45 onto the light-extracting surface 30b to form the droplet Dm, and the microlens 40 is formed by irradiating this droplet Dm with ultraviolet rays. Accordingly, the microlens 40 can be formed without having restrictions on the thickness of the element substrate 30. As a result, it is possible to design the post-grind thickness T1 of the element substrate 30 based on processing performance of the grinding process and to further improve the light extraction efficiency of the exposure head 20.

Additionally, the embodiment as hereinbefore described may be modified as below.

In the embodiment, the element substrate 30 is mechanically ground so that its thickness is reduced to the post-grind thickness T1. However, the grinding surface 30c of the element substrate 30 may, for example, be immersed in diluted hydrofluoric acid or a mixed solution of diluted hydrofluoric acid and ammonium fluoride or etched in a mixed solution or the like of hydrochloric acid and nitric acid so as to obtain the post-grind thickness T1. Further, in this case, it is preferable to specify the post-grind thickness T1 of the substrate to be of an even thickness obtainable by the etching or the like.

In the embodiment, the droplet Dm is formed by discharging the ultraviolet curing resin Pu onto the light-extracting surface 30b which was formed in the grinding process. In addition to this process, the droplet Dm may be formed by discharging the ultraviolet curing resin Pu after performing a liquid repellent treatment (such as a plasma treatment under fluorine condition or application of a liquid repellent material) for smoothing out the surface of the light-extracting surface 30b. Accordingly, the droplet Dm having the half spherical surface can be evenly formed without allowing the minute droplet Ds to wet and diffuse.

In the embodiment, the element substrate 30 is exemplified as the transparent substrate. However, the transparent substrate may be a substrate made of plastic such as polyimide, for example, provided that it transmits the light emitted from the organic EL layer OEL.

In the embodiment, the aperture diameter R2 of the microlens 40 is formed to be twice as large as the inner diameter (the matching diameter R1) of the organic EL layer OEL. However, the aperture diameter R2 may be of any size provided that it does not let the image quality deteriorate in an area surrounding the microlens 40 and that it can produce the exposure spot of a desired size corresponding to each organic EL layer OEL.

In the embodiment, the microlens 40 is the half spherical convex lens. However, the microlens 40 may be a half cylindrical lens or a concave lens. Accordingly, diffusion efficiency of the light emitted from the organic EL element 33 can be further improved.

In the embodiment, the microlens 40 is made of the ultraviolet curing resin Pu. However, the microlens 40 may be made of a thermosetting resin, for example, so long as it is a functional liquid cured on the light-extracting surface 30b.

The embodiment has a configuration in that the microlens 40 is formed using the droplet discharge apparatus. However, the method for forming the microlens 40 may have a configuration in that the microlens 40 formed by a replica method is attached to the light-extracting surface 30b, for example.

In the embodiment, the distance between the vertex of the emitting surface 40a and the photosensitive layer 16a is the image-side focal distance Hf, and the light emitted from the organic EL layer OEL is converged on the photosensitive layer 16a. However, the distance between the vertex of the emitting surface 40a and the photosensitive layer 16a is not limited to the image-side focal distance Hf but may be a distance that can produce, for example, an equal size image of the organic EL layer OEL.

In the embodiment, one TFT 32 that controls light emission of the organic EL element 33 is provided per each pixel 34. However, two or more TFTs 32 that control light emission of the organic EL element 33 may be provided per each pixel 34, or there may be no TFT 32 provided on the element substrate 30.

In the embodiment, the organic EL layer OEL is formed by the ink-jet method. However, the method for forming the organic EL layer OEL is not limited to the ink-jet method but may be a spin coating method or a vacuum deposition method.

In the embodiment, the organic EL layer OEL is composed of a macromolecular organic material. However, the organic EL layer OEL may be composed of a low-molecular organic material, or, further, it may be an EL layer composed of an inorganic material.

In the embodiment, the exposure head 20 is exemplified as the electrooptical device. However, the electrooptical device may be, for example, a backlight or the like attached to a liquid crystal panel or a field effect display (e.g., FED or SED) which is equipped with a planer-shaped electron-emitting element and uses light emitted from a fluorescent material by electrons output from this element.

What is claimed is:

1. A method for manufacturing an electrooptical device, in which a luminous element is formed on a luminous element formation surface of a transparent substrate and in which a microlens that outputs light emitted from the luminous element is formed on a light-extracting surface of the transparent substrate, comprising:
forming the light-extracting surface by grinding one surface of the transparent substrate opposite from the luminous element formation surface towards the luminous element formation surface after applying a support substrate to the luminous element formation surface side of the transparent substrate.

2. The method for manufacturing the electrooptical device according to claim 1, further comprising forming the light-extracting surface by grinding the one surface of the transparent substrate.

3. The method for manufacturing the electrooptical device according to claim 1, further comprising forming the light-extracting surface by etching the one surface of the transparent substrate.

4. The method for manufacturing the electrooptical device according to claim 1, further comprising forming the microlens by forming a droplet on the light-extracting surface using a functional liquid discharged from a droplet discharging apparatus and by curing the droplet.

5. The method for manufacturing the electrooptical device according to claim 4, further comprising forming the microlens in a convex shape by forming the droplet in a half spherical shape on the light-extracting surface at a position opposite from the luminous element and by curing the droplet.

6. The method for manufacturing the electrooptical device according to claim 1, wherein the luminous element is an electroluminescence element containing a transparent electrode formed on the light-extracting surface side, a rear surface electrode formed opposite from the transparent electrode, and a luminescent layer formed between the transparent electrode and the rear surface electrode.

7. The method for manufacturing the electrooptical device according to claim 6, wherein the luminescent layer is formed using an organic material, and the electroluminescence element is an organic electroluminescence element.

8. An image forming apparatus having a charging unit that charges the peripheral surface of an image carrier, an exposure unit that exposes the charged peripheral surface of the image carrier so as to form a latent image, a developing unit that develops an image by supplying coloring particles to the latent image, and a transfer unit that transfers the developed image to a transfer medium, wherein:
the exposure unit is provided with the electrooptical device manufactured by the electrooptical device manufacturing method according to claim 1.
